(19) United States
(12) Patent Application Publication
(10) Pub. No.: US 2026/0344152 A1
(43) Pub. Date: Oct. 29, 2026

(54) ACTIVE MATRIX LED SOUND SCREEN

(71) Applicant: Ennostar Corporation, Hsinchu City (TW)

(72) Inventors: Zheng-Shuo TUNG, Hsinchu City (TW); Kai-Hsiang SHIH, Hsinchu City (TW); Cheng-Yeh TSAI, Hsinchu City (TW); Jung-Chien CHANG, Hsinchu City (TW); Chien-Nan YEH, Hsinchu City (TW)

(21) Appl. No.: 19/658,248

(22) Filed: Apr. 24, 2026

(30) Foreign Application Priority Data
Apr. 29, 2025 (TW) 114116139

(51) Int. Cl. H10H 29/49; H10H 29/34; H10H 29/85

(52) U.S. Cl. CPC H10H 29/49; H10H 29/34; H10H 29/8517

(57) ABSTRACT

An active matrix LED acoustically transparent screen (sound screen) is provided. The active matrix LED acoustically transparent screen includes a circuit substrate, a plurality of active matrix LED pixel packages, a plurality of data lines, a plurality of clock lines, and a plurality of holes. The active matrix LED pixel packages are provided on the circuit substrate. The data lines are electrically connected to the active matrix LED pixel packages. The clock lines are electrically connected to the active matrix LED pixel packages. The holes penetrate through the circuit substrate. The holes are formed in a perforable area on the circuit substrate. The perforable area does not overlap the positions of the active matrix LED pixel packages, the data lines, and the clock lines on the circuit substrate. The perforable area occupies at least 8.0% of the circuit substrate.

### CROSS REFERENCE TO RELATED APPLICATIONS

This application claims priority of Taiwan patent application No. 114116139, filed on Apr. 29, 2025, the entirety of which is incorporated by reference herein.

### TECHNICAL FIELD

The present disclosure relates to acoustically transparent screens (sound screens), and, in particular it relates to active matrix LED (light-emitting diode) acoustically transparent screens.

### BACKGROUND

Conventionally, acoustically transparent screens are provided with holes, such that the sound can pass through the holes and be transmitted to the ears of the audience. However, the performance of existing acoustically transparent screens is not been satisfactory in all respects. For example, the hole ratio of current LED acoustically transparent screens may be insufficient, resulting in poor sound transmission. According to Digital Cinema Initiatives (DCI) standards, the hole ratio should be within a range of 4.0% to 6.3%.

### BRIEF SUMMARY

Some embodiments of the present disclosure provide an active matrix LED acoustically transparent screen. The active matrix LED acoustically transparent screen includes a circuit substrate, a plurality of active matrix LED pixel packages, a plurality of data lines, a plurality of clock lines, and a plurality of holes. The active matrix LED pixel packages are provided on the circuit substrate. The data lines are electrically connected to the active matrix LED pixel packages. The clock lines are electrically connected to the active matrix LED pixel packages. The holes penetrate through the circuit substrate and are formed in a perforable area on the circuit substrate. The perforable area does not overlap the positions of the active matrix LED pixel packages, the data lines, and the clock lines. The perforable area occupies at least 8.0% of the circuit substrate.

In some embodiments, the holes occupy at least 6.0% of the circuit substrate. In some embodiments, the perforable area occupies at least 30.0% of the circuit substrate, and the holes occupy at least 25.0% of the circuit substrate. In some embodiments, the size of one of the active matrix LED pixel packages is less than the size of one of the holes.

In some embodiments, the active matrix LED pixel packages are arranged in multiple rows, and the active matrix LED pixel packages in the same row are arranged at the same first pitch. In some embodiments, the first pitch is between 2.00 mm and 6.00 mm. In some embodiments, the size of any of the holes is not greater than the first pitch minus 0.90 mm. In some embodiments, the holes are arranged in multiple rows, and the holes in the same row are arranged at the same second pitch. In some embodiments, the second pitch is different from the first pitch. In some embodiments, the ratio of the second pitch to the first pitch is between 1.5 and 2.5.

In some embodiments, each of the active matrix LED pixel packages includes one or more red sub-pixels, one or more green sub-pixels, one or more blue sub-pixels, and an LED driving control element.

In some embodiments, the active matrix LED acoustically transparent screen further includes a display driver IC element. The active matrix LED pixel packages are disposed on one surface of the circuit substrate, the display driver IC element is disposed on the opposite surface of the circuit substrate, and the position of the display driver IC element does not overlap with the perforable area.

### BRIEF DESCRIPTION OF THE DRAWINGS

The present disclosure may be more fully understood by reading the detailed description and examples with references made to the accompanying drawings. It should be noted that various features may be not drawn to scale. In fact, the dimensions of the various features may be arbitrarily increased or decreased for clarity of discussion, and the various features may be drawn schematically.

FIG. 1 illustrates an imaging system architecture according to some embodiments of the present disclosure.

FIGS. 2A and 2B are front and rear views of an active matrix LED acoustically transparent screen according to some embodiments of the present disclosure.

FIG. 3 is a side view of an active matrix LED acoustically transparent screen according to some embodiments of the present disclosure.

FIGS. 4A, 4B, 4C, and 4D are schematic views of a plurality of active matrix LED pixel packages according to some embodiments of the present disclosure.

FIG. 5 is a side view of an active matrix LED pixel package according to some embodiments of the present disclosure.

FIG. 6 is a partially enlarged schematic view of an active matrix LED acoustically transparent screen according to some embodiments of the present disclosure.

FIGS. 7A, 7B, 7C, and 7D are partially enlarged schematic views of active matrix LED acoustically transparent screens according to some embodiments of the present disclosure.

### DETAILED DESCRIPTION

The following description provides different embodiments, or examples, for implementing different features of the present disclosure. In addition, spatially relative terms may be used in the following description to describe the arrangements of various features. These spatially relative terms are for ease of describing the positional relationship between one feature and another feature as illustrated in the drawings. These spatially relative terms are intended to encompass different orientations of the device in use or operation in addition to the orientation illustrated in the drawings. The device may be otherwise oriented (rotated 90 degrees or at other orientations), and the spatially relative terms used in the following description may likewise be interpreted accordingly. For example, if a device of the drawings is flipped upside down, a feature that is “above” will become a feature that is “below”.

For example, the formation of a first feature “on,” “over,” or “under” a second feature in the following description may include embodiments in which the first and second features are formed in direct contact, and may also include embodiments in which additional features may be formed between the first feature and the second feature, such that the first feature and the second feature are not in direct contact.

In the following description, the terms “including”, “comprising”, “having”, and the like should be interpreted as meaning “including but not limited to...”. Therefore, when the terms “including”, “comprising”, “having”, and the like are used, the presence of corresponding features, regions, steps, operations and/or elements is specified, and without excluding the presence of other features, regions, steps, operations and/or elements.

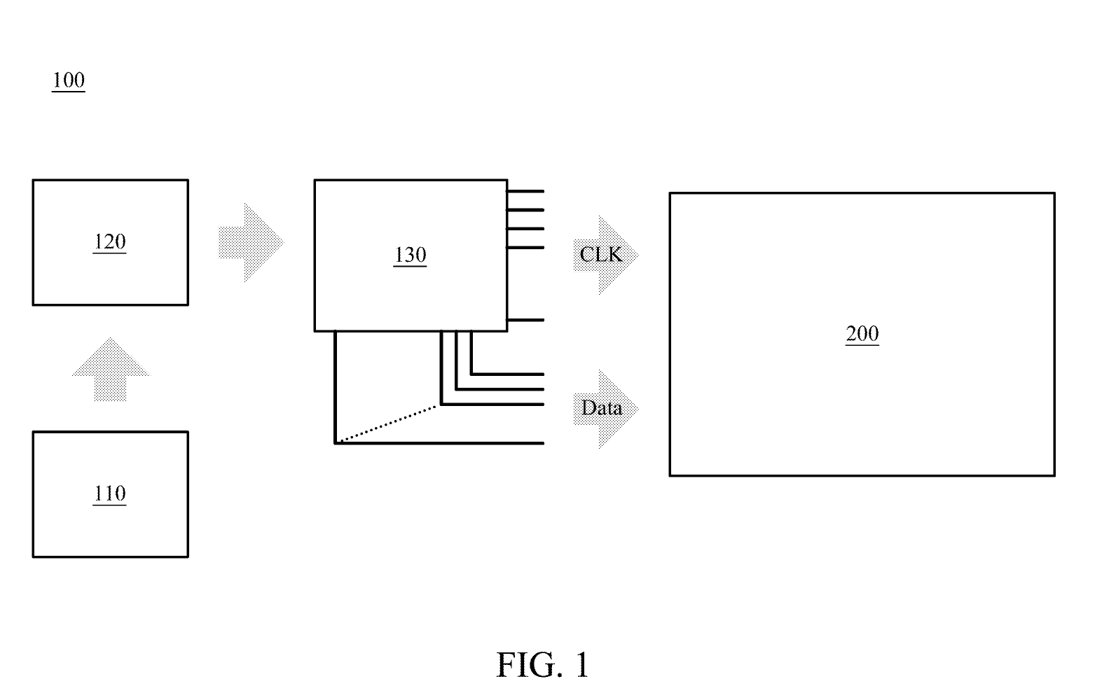

Refer to FIG. 1 to understand an imaging system 100. FIG. 1 illustrates the architecture of the imaging system 100 according to some embodiments of the present disclosure. The imaging system 100 includes an input device 110, a signal processing device 120, a timing control device 130, and an active matrix LED acoustically transparent screen 200. In the present disclosure, the terms “active matrix,” “active driving,” or “active matrix driving” mean that the control is performed using digital signals without the use of scanning lines.

The input device 110 may be used as an image source, and may transmit the image signal to the signal processing device 120 through a transmission method such as a high definition multimedia interface (HDMI). The signal processing device 120 may process the received image signal. If necessary, the signal processing device 120 may convert the received image signal into a suitable format. The signal processing device 120 may transmit the image signal to the timing control device 130 through a transmission method such as a serial peripheral interface (SPI) and/or a low-voltage differential signaling (LVDS).

The timing control device 130 may be used to control the timing and/or synchronization of the light-emitting units (such as the active matrix LED pixel packages 240 described below) on the active matrix LED acoustically transparent screen (sound screen) 200. Specifically, the timing control device 130 may generate digital signals, including clock (CLK) signals and data signals to drive the light-emitting units on the active matrix LED acoustically transparent screen 200. The timing control device 130 may ensure that the digital signals in the active matrix driving are transmitted in a suitable and relatively precise manner.

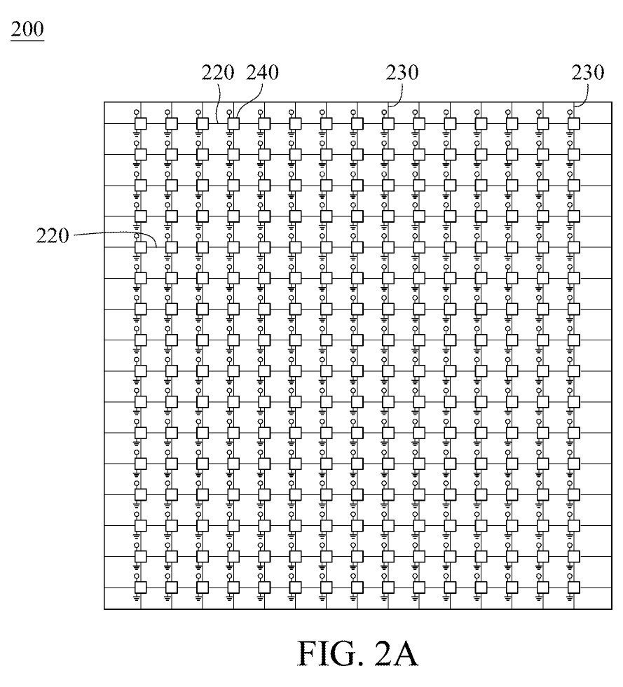

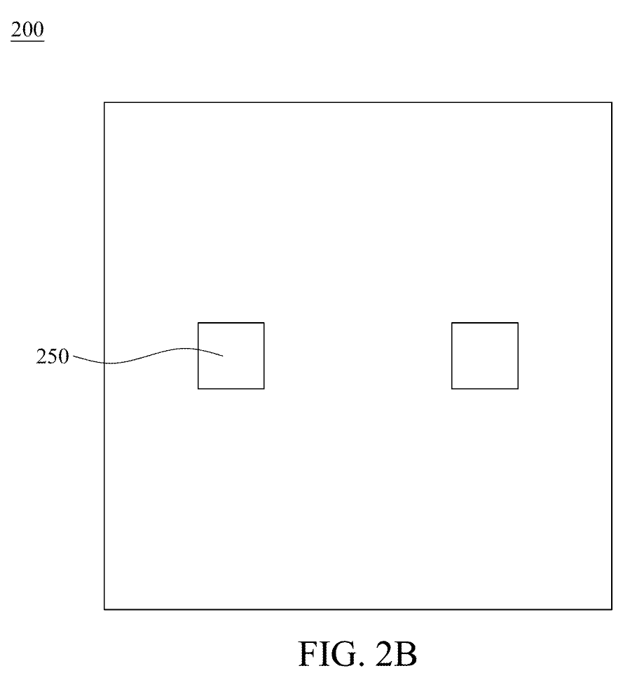

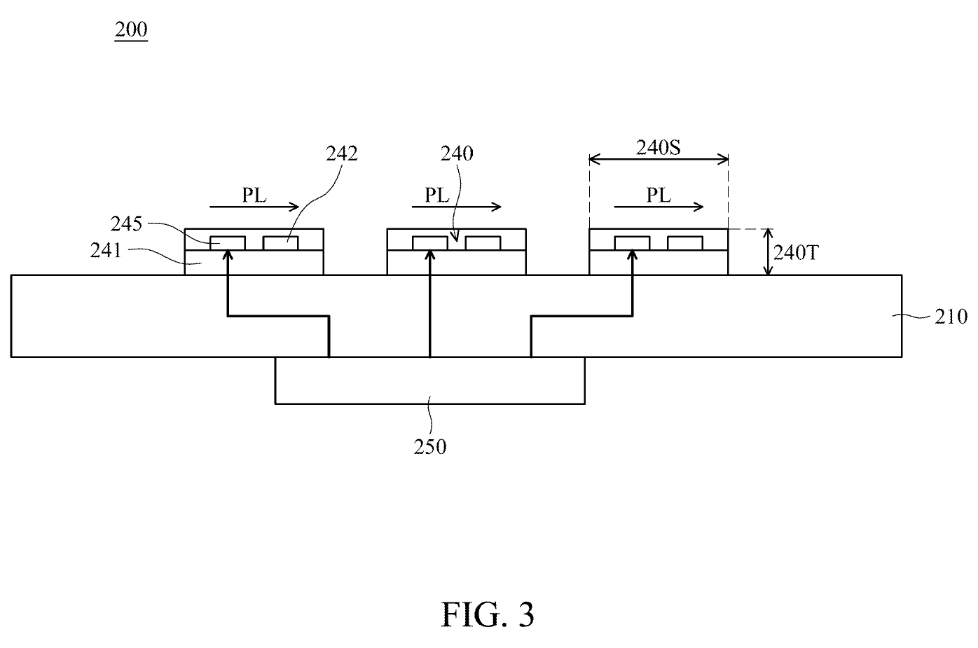

Next, refer to FIGS. 2A and 2B, and 3 to understand the active matrix LED acoustically transparent screen 200. FIGS. 2A and 2B are front and rear views of the active matrix LED acoustically transparent screen 200 according to some embodiments of the present disclosure. FIG. 3 is a side view of the active matrix LED acoustically transparent screen 200 according to some embodiments of the present disclosure.

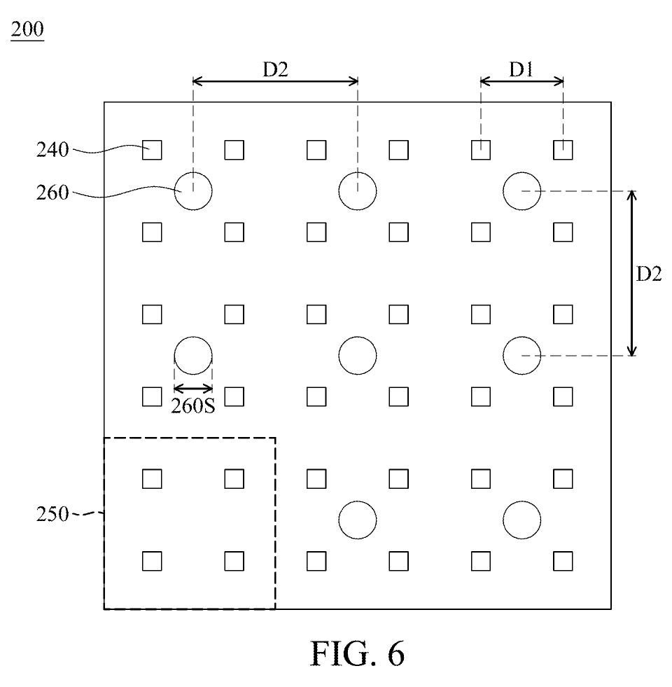

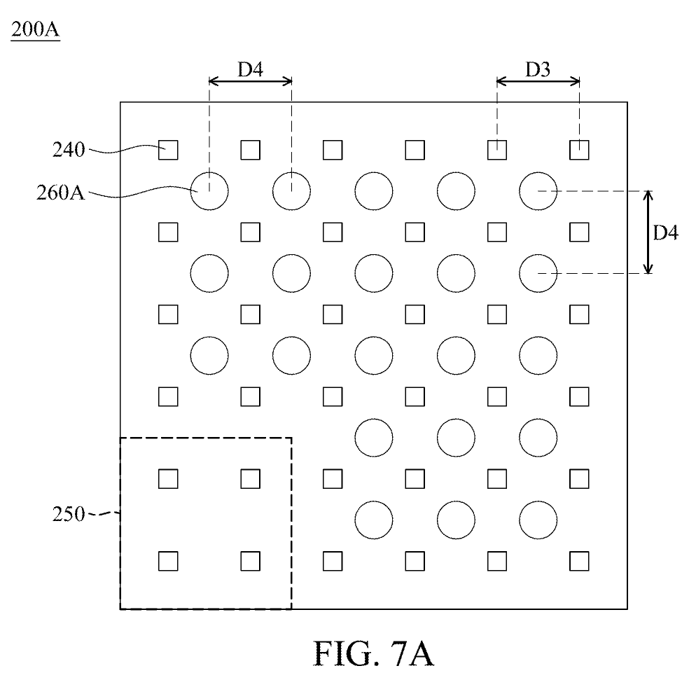

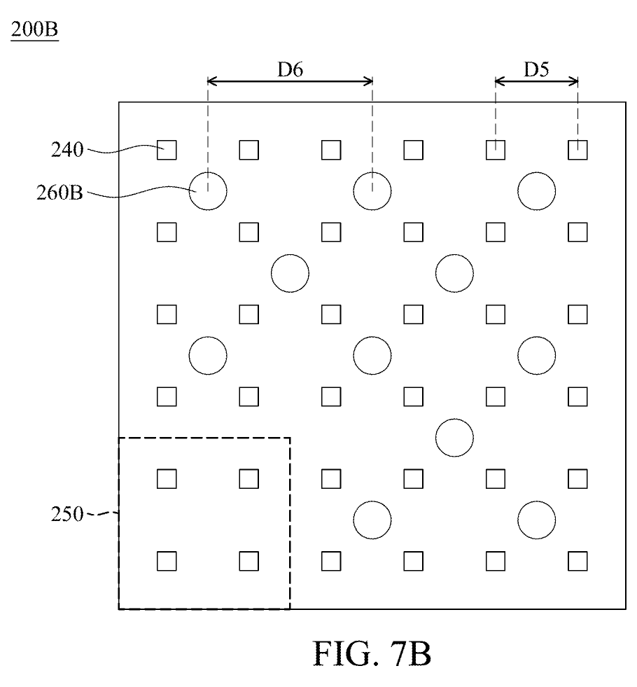

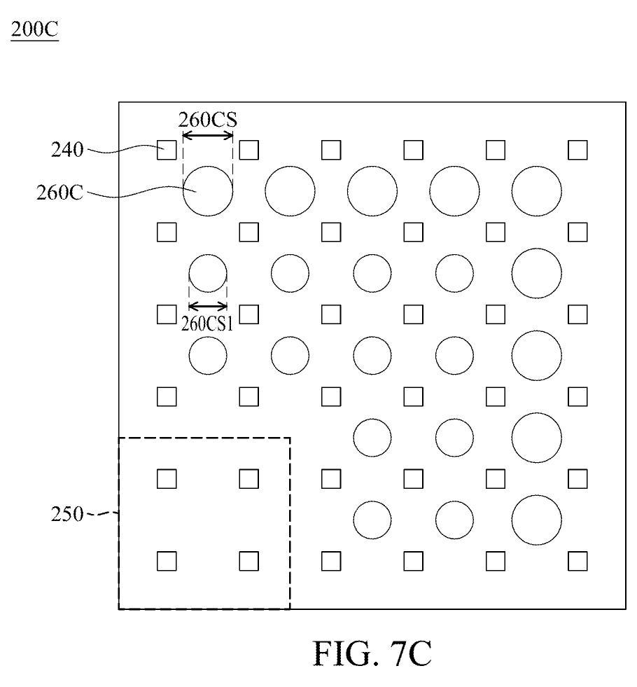

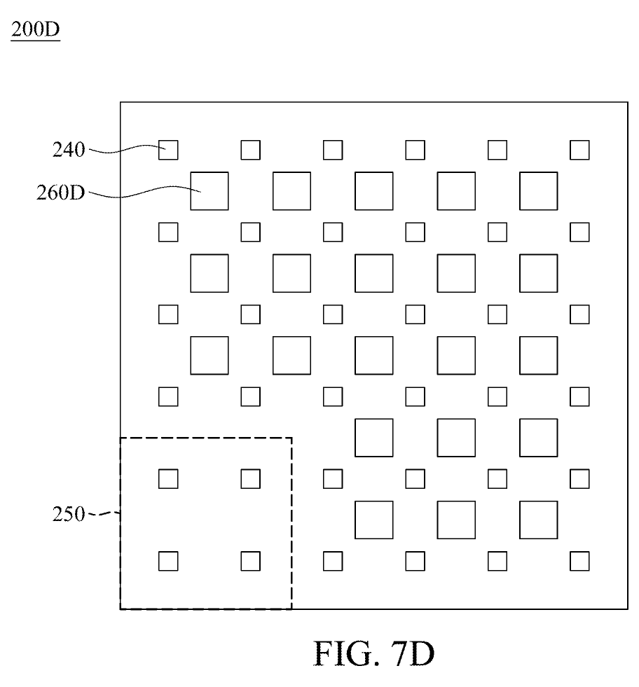

The active matrix LED acoustically transparent screen 200 may include a circuit substrate 210, a plurality of clock lines 220, a plurality of data lines 230, a plurality of active matrix LED pixel packages 240, at least one display driver integrated circuit (DDIC) element 250, and a plurality of holes 260 for transmitting sound. For ease of illustration, the holes 260 are not shown in FIGS. 2A and 2B, and 3. The holes 260 will be further described with respect to FIGS. 6 and 7A-7D. In some embodiments, an audio equipment may be disposed on the back side (i.e., the side facing away from the audience) of the active matrix LED acoustically transparent screen 200, allowing sound to be transmitted through the holes 260 and/or amplifying the audio signals perceived by the audience.

In some embodiments, the circuit substrate 210 may be a flexible board, a metal substrate, a semiconductor substrate or other substrates with circuits, etc. In some embodiments, the circuit substrate 210 has an even number of layers, for example, the circuit substrate 210 may have four layers, six layers, or eight layers, etc.

The clock lines 220 are electrically connected to the active matrix LED pixel packages 240. In some embodiments, each clock line 220 corresponds to the same row of active matrix LED pixel packages 240. The clock lines 220 may control the timing of data transmission.

The data lines 230 are electrically connected to the active matrix LED pixel packages 240. In some embodiments, each data line 230 corresponds to the same column of active matrix LED pixel packages 240. The data lines 230 may carry pixel information.

As shown in FIG. 2A, the multiple active matrix LED pixel packages 240 are disposed on the circuit substrate 210. The active matrix LED pixel packages 240 may be arranged in multiple rows and multiple columns. In some embodiments, the active matrix LED pixel packages 240 are arranged in a matrix. In some embodiments, each active matrix LED pixel package 240 includes a base 241, a plurality of LEDs 242 (only one LED 242 is shown in FIG. 3 due to the perspective), and an LED driving control element 245.

In some embodiments, each LED 242 may be a mini-LED or a micro-LED, which is smaller in size. A micro-LED may include an N-type semiconductor layer, a light-emitting layer, and a P-type semiconductor layer, and the light-emitting layer is disposed between the N-type semiconductor layer and the P-type semiconductor layer. The light emitted by the micro-LED structure is determined by the light-emitting layer.

The N-type semiconductor layer may include a Group II-VI material (e.g., zinc selenide (ZnSe)) or a Group III-V material (e.g., gallium nitride (GaN), aluminum nitride (AlN), indium nitride (InN), indium gallium nitride (InGaN), aluminum gallium nitride (AlGaN), or aluminum indium gallium nitride (AlInGaN)), and the N-type semiconductor layer may include dopants such as silicon (Si) or germanium (Ge), but the present disclosure is not limited thereto.

The light-emitting layer may include at least one undoped semiconductor layer or at least one low-doped layer. For example, the light-emitting layer may be a quantum well (QW) layer, which may include indium gallium nitride (InₓGa₁₋ₓN), gallium nitride (GaN), aluminum gallium nitride (AlGaN) or aluminum indium gallium nitride (AlInGaN), but the present disclosure is not limited thereto. Alternatively, the light-emitting layer may also be a multiple quantum well (MQW) layer.

The P-type semiconductor layer may include a II-VI group material (e.g., zinc selenide (ZnSe)) or a III-V group material (e.g., gallium nitride (GaN), aluminum nitride (AlN), indium nitride (InN), indium gallium nitride (InGaN), aluminum gallium nitride (AlGaN) or aluminum indium gallium nitride (AlInGaN)), and the P-type semiconductor layer may include dopants such as magnesium (Mg) and carbon (C), but the present disclosure is not limited thereto. In addition, the N-type semiconductor layer and the P-type semiconductor layer may be a single-layer structure or a multi-layer structure.

In some embodiments, the LED driving control element 245 is an element that may control the execution of a predetermined electronic function (e.g., a diode, a transistor, an IC), and is used to control the operation of the LEDs 242. In some embodiments, the LED driving control element 245 may also be a microchip made of silicon or semiconductor-on-insulator (SOI) wafers and used for logic or memory applications, or a microchip made of gallium arsenide (GaAs) wafers and used for RF communication applications, but the present disclosure is not limited thereto. The LED driving control element 245 may include a power pin for receiving a power source and a driving pin connected to the LEDs 242.

In some embodiments, the packaging thickness 240T of the active matrix LED pixel package 240 is less than 0.15 mm. In some embodiments, the packaging size 240S (e.g., length and/or width) of the active matrix LED pixel package 240 is between 0.15 mm and 0.40 mm, for example, it may be about 0.20 mm, or about 0.30 mm.

The DDIC element 250 is disposed on the circuit substrate 210. In some embodiments, the active matrix LED pixel packages 240 are disposed on one surface of the circuit substrate 210, and the DDIC element 250 is disposed on the opposite surface of the circuit substrate 210. For example, the active matrix LED pixel package 240 may be disposed on the front side of the circuit substrate 210 (i.e., the side facing the audience), and the DDIC element 250 may be disposed on the back side of the circuit substrate 210 (i.e., the side facing away from the audience).

Since the LED acoustically transparent screen disclosed herein uses a plurality of active matrix LED pixel packages, the control is performed using digital signals without the use of scanning lines. Compared to the conventional passive matrix driving that require scanning lines, the present disclosure may simplify circuit routing and effectively utilize space. In addition, because the passive matrix driving require scanning lines, it may produce flicker phenomena. The active matrix driving may provide higher uniformity and/or higher stability.

Moreover, because each LED driving control element 245 for controlling the operation of the LEDs 242 is packaged in one of the active matrix LED pixel packages 240, the signal transmission path length PL is relatively short, for example, the signal transmission path length PL may be about 0.01 mm. Compared to the passive matrix driving with signal transmission path length usually between 1.50 mm and 15.00 mm, the present disclosure may effectively shorten the signal transmission path, thereby improving the performance of the active matrix LED acoustically transparent screen 200, including but not limited to contrast, clarity, etc. That is, because the LED driving control element 245 is located in the active matrix LED pixel package 240, the overall circuit routing of the active matrix LED acoustically transparent screen 200 may be simplified, and the perforable area for forming the hole 260 (for sound transmission) may be increased.

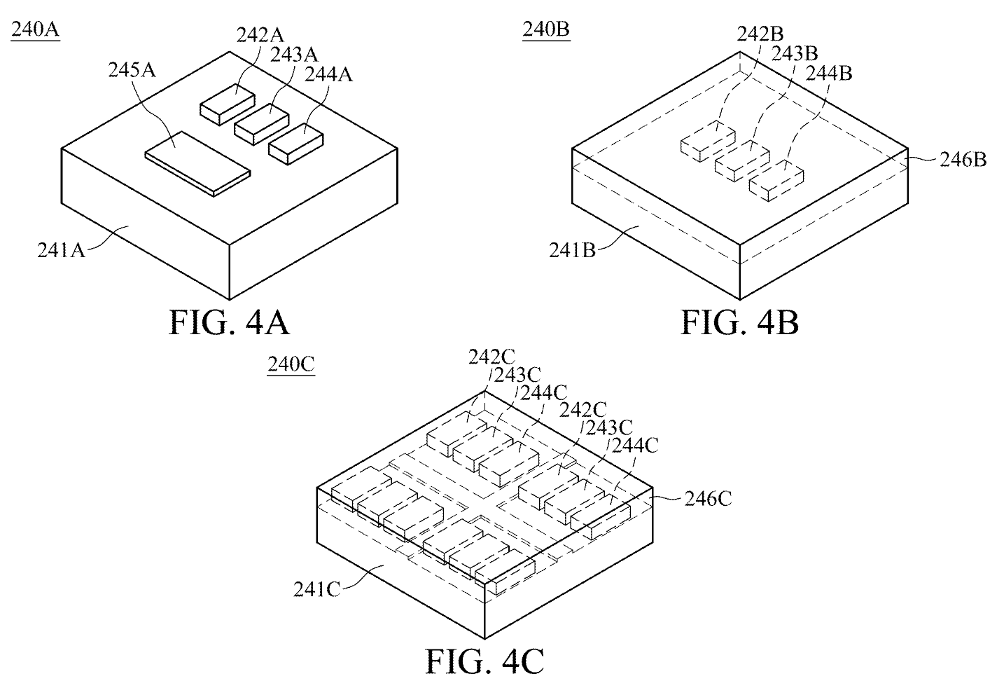

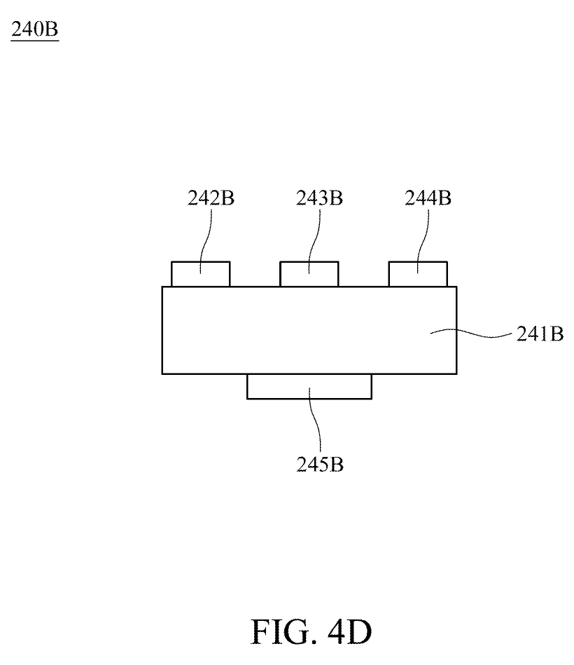

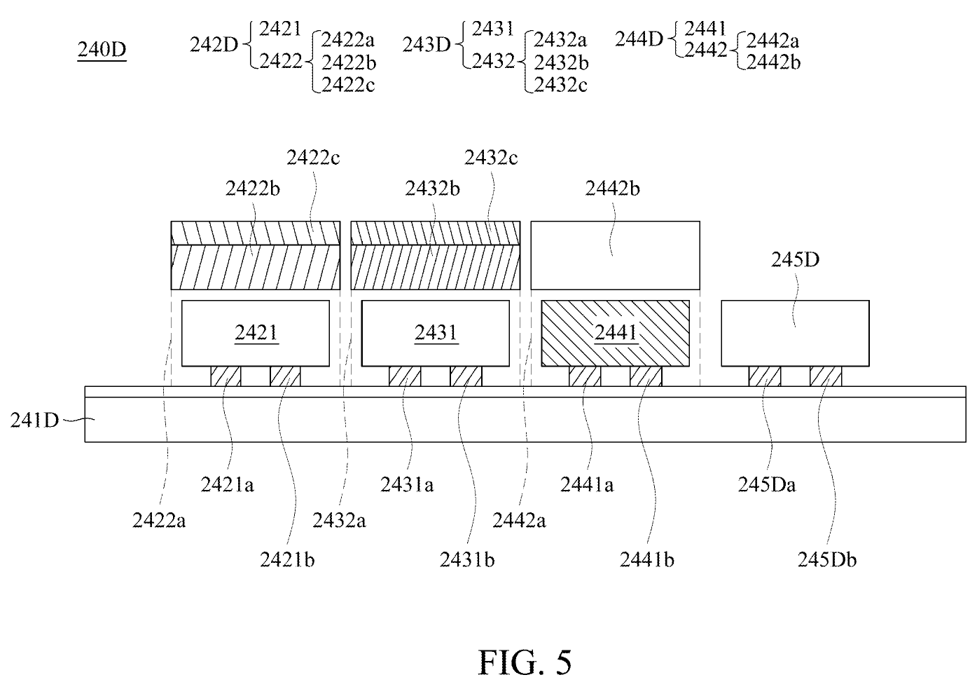

FIGS. 4A to 4D, and 5 are used to illustrate different embodiments of the active matrix LED pixel packages 240, and the same or similar elements will be labeled with the same or similar reference numerals. FIGS. 4A, 4B, 4C, and 4D are schematic views of a plurality of active matrix LED pixel packages 240A, 240B, 240C, and 240D according to some embodiments of the present disclosure. FIG. 5 is a side view of the active matrix LED pixel package 240D according to some embodiments of the present disclosure. Specifically, the active matrix LED pixel packages 240 may include but are not limited to the configurations shown in the active matrix LED pixel packages 240A, 240B, 240C, and 240D.

In the embodiments illustrated in FIG. 4A, each active matrix LED pixel package 240A includes a base 241A, a red sub-pixel 242A, a green sub-pixel 243A, a blue sub-pixel 244A, and an LED driving control element 245A. The red sub-pixel 242A, the green sub-pixel 243A, the blue sub-pixel 244A, and the LED driving control element 245A are disposed on the same side of the base 241A. For example, the red sub-pixel 242A, the green sub-pixel 243A, the blue sub-pixel 244A, and the LED driving control element 245A are all disposed on the front side (e.g., the upper surface) of the base 241A.

In the embodiments illustrated in FIGS. 4B and 4D, each active matrix LED pixel package 240B includes a base 241B, a red sub-pixel 242B, a green sub-pixel 243B, a blue sub-pixel 244B, and an LED driving control element 245B. The red sub-pixel 242B, the green sub-pixel 243B, the blue sub-pixel 244B are disposed on one side of the base 241B, and the LED driving control element 245B is disposed on the opposite side of the base 241B. For example, the red sub-pixel 242B, the green sub-pixel 243B, and the blue sub-pixel 244B may be disposed on the front side (e.g., the upper surface) of the base 241B, and the LED driving control element 245B may be disposed on the back side (e.g., the lower surface) of the base 241B.

In the embodiments shown in FIG. 4C, each active matrix LED pixel package 240C includes a base 241C, a plurality of red sub-pixels 242C, a plurality of green sub-pixels 243C, a plurality of blue sub-pixels 244C, and an LED driving control element (not shown due to the perspective). The red sub-pixel 242C, the green sub-pixel 243C, the blue sub-pixel 244C are disposed on one side of the base 241C, and the LED driving control element is disposed on the opposite side of the base 241C. For example, the red sub-pixel 242C, the green sub-pixel 243C, and the blue sub-pixel 244C may be disposed on the front side (e.g., the upper surface) of the base 241C, and the LED driving control element may be disposed on the back side (e.g., the lower surface) of the base 241C.

In the embodiments shown in FIGS. 4A, 4B, and 4D, since a single LED driving control element 245A, 245B drives a group of RGB pixels, it may be referred to as one-to-one control. In the embodiments shown in FIG. 4C, since a single LED driving control element drives multiple groups of RGB pixels, it may be referred to as one-to-many control.

In addition, as shown in FIGS. 4B to 4D, the active matrix LED pixel package 240B and 240C may further include a covering layer 246B and a covering layer 246C respectively. In some embodiments, the covering layer 246B, 246C includes a light-transparent material. The covering layer 246B covers the red sub-pixel 242B, the green sub-pixel 243B, and the blue sub-pixel 244B. The covering layer 246C covers the red sub-pixel 242C, the green sub-pixel 243C, and the blue sub-pixel 244C. If necessary, the active matrix LED pixel package 240A in FIG. 4A may also include a covering layer covering the red sub-pixel 242A, the green sub-pixel 243A, and the blue sub-pixel 244A.

In some embodiments, the red sub-pixel (such as the red sub-pixels 242A, 242B, and 242C described above) includes a red LED chip, the green sub-pixel (such as the green sub-pixels 243A, 243B, and 243C described above) includes a green LED chip, and the blue sub-pixel (such as the blue sub-pixels 244A, 244B, and 244C described above) includes a blue LED chip, but the present disclosure is not limited to this.

In the embodiments shown in FIG. 5, each active matrix LED pixel package 240D includes a base 241D, a red sub-pixel 242D, a green sub-pixel 243D, a blue sub-pixel 244D, and an LED driving control element 245D. In some embodiments, the red sub-pixel 242D includes a first blue LED chip 2421 and a first light adjustment unit 2422. In some embodiments, the green sub-pixel 243D includes a second blue LED chip 2431 and a second light adjustment unit 2432. In some embodiments, the blue sub -pixel 244D includes a third blue LED chip 2441 and a third light adjustment unit 2442. The first blue LED chip 2421, the second blue LED chip 2431, and the third blue LED chip 2441 may emit blue light.

The first blue LED chip 2421 has two electrodes 2421a and 2421b, one of which is electrically connected to the P-type semiconductor layer of the first blue LED chip 2421 as a positive electrode, and the other is electrically connected to the N-type semiconductor layer of the first blue LED chip 2421 as a negative electrode. The second blue LED chip 2431 has two electrodes 2431a and 2431b, one of which is electrically connected to the P-type semiconductor layer of the second blue LED chip 2431 as a positive electrode, and the other is electrically connected to the N-type semiconductor layer of the second blue LED chip 2431 as a negative electrode. The third blue LED chip 2441 has two electrodes 2441a and 2441b, one of which is electrically connected to the P-type semiconductor layer of the third blue LED chip 2441 as a positive electrode, and the other is electrically connected to the N-type semiconductor layer of the third blue LED chip 2441 as a negative electrode.

The electrodes 2421a, 2421b, 2431a, 2431b, 2441a, and 2441b include conductive materials, such as metals, metal silicides, similar materials, or combinations thereof, but the present disclosure is not limited thereto. For example, the metal may include gold (Au), nickel (Ni), platinum (Pt), palladium (Pd), iridium (Ir), titanium (Ti), chromium (Cr), tungsten (W), aluminum (Al), copper (Cu), similar materials, alloys of the aforementioned metals, or combinations thereof, but the present disclosure is not limited thereto.

The first light adjustment unit 2422 includes a first light extraction layer 2422a, a first wavelength conversion layer 2422b, and a first filter layer 2422c. The first light extraction layer 2422a is disposed on the first blue LED chip 2421, the first wavelength conversion layer 2422b is located between the first light extraction layer 2422a and the first filter layer 2422c, and the first filter layer 2422c is disposed on the first wavelength conversion layer 2422b.

The second light adjustment unit 2432 includes a second light extraction layer 2432a, a second wavelength conversion layer 2432b, and a second filter layer 2432c. The second light extraction layer 2432a is disposed on the second blue LED chip 2431, the second wavelength conversion layer 2432b is located between the second light extraction layer 2432a and the second filter layer 2432c, and the second filter layer 2432c is disposed on the second wavelength conversion layer 2432b.

The third light adjustment unit 2442 includes a third light extraction layer 2442a and a transparent light outcoupling layer 2442b. The third light extraction layer 2442a is disposed on the third blue LED chip 2441, and the transparent light outcoupling layer 2442b is disposed on the third light extraction layer 2442a.

The first light extraction layer 2422a, the second light extraction layer 2432a, and the third light extraction layer 2442a may be transparent layers and may be made of the same material. Moreover, the transparent light outcoupling layer 2442b may include the same or similar material as the third light extraction layer 2442a.

In some embodiments, the first wavelength conversion layer 2422b and the second wavelength conversion layer 2432b each include phosphor, a quantum dot material, or a combination thereof. For example, the first wavelength conversion layer 2422b may include red phosphor, a red quantum dot material, or a combination thereof, and the second wavelength conversion layer 2432b may include green phosphor, a green quantum dot material, or a combination thereof, but the present disclosure is not limited thereto.

In some embodiments, the first wavelength conversion layer 2422b absorbs part of the blue light emitted by the first blue LED chip 2421 and converts it into red light, while the second wavelength conversion layer 2432b absorbs part of the blue light emitted by the second blue LED chip 2431 and converts it into green light. The blue light emitted by the third blue LED chip 2441 may be emitted through the transparent light outcoupling layer 2442b.

In addition, the first filter layer 2422c and the second filter layer 2432c may, for example, filter out unconverted blue light, so that the color of the light converted by the first wavelength conversion layer 2422b or the second wavelength conversion layer 2432b is closer to the color of the material included therein (e.g., the phosphor, the quantum dot material or the combination thereof), but the present disclosure is not limited thereto. In some embodiments, the first filter layer 2422c and the second filter layer 2432c may be omitted.

The LED driving control element 245D may be used to control the first blue LED chip 2421, the second blue LED chip 2431, and the third blue LED chip 2441. In some embodiments, the LED driving control element 245D may have two electrodes 245Da and 245Db, but the present disclosure is not limited thereto.

Next, refer to FIG. 6 to understand a perforable area and the multiple holes 260. FIG. 6 is a partially enlarged schematic view of the active matrix LED acoustically transparent screen 200 according to some embodiments of the present disclosure. For ease of illustration, FIG. 6 is illustrated in a schematic manner, and the DDIC element 250, which is disposed on the back side of the circuit substrate 210, is represented by dotted lines.

The holes 260 are formed such that they penetrate through the circuit substrate 210. To reduce the possibility of the holes 260 damaging other elements or rendering other elements inoperable, the holes 260 may be formed only within a perforable area of the circuit substrate 210 that does not overlap the positions of any other elements. In some embodiments, the perforable area refers to a region on the circuit substrate 210 that does not overlap the positions of the clock lines 220, the data lines 230, the active matrix LED pixel packages 240, and the DDIC element 250. Specifically, FIG. 6 illustrates that the area overlapping with the DDIC element 250 is excluded from the perforable area, and thus no hole 260 is formed therein.

In some embodiments, the active matrix LED acoustically transparent screen 200 further includes a plurality of magnetic elements that may provide magnetic force for adsorption to other devices. In such an embodiment, the perforable area is a region on the circuit substrate 210 that does not overlap the positions of the clock lines 220, the data lines 230, the active matrix LED pixel packages 240, the DDIC element 250, and the magnetic elements.

Since the present disclosure adopts active matrix driving, its circuit routing is relatively simple. This allows for a relatively high proportion of perforable area on the active matrix LED acoustically transparent screen 200, and the ratio of the holes 260 to the circuit substrate 210 (i.e., the hole ratio) may readily meet relevant specifications and fulfill the requirements of the acoustically transparent screen. Moreover, because the proportion of the perforable area is relatively high, the flexibility of the design of the holes 260 formed in the perforable area is increased, and the overall strength of the active matrix LED acoustically transparent screen 200, especially the strength of the circuit substrate 210, is taken into account. Specifically, compared to the acoustically transparent screen using passive matrix driving, the present disclosure may effectively increase the proportion of the perforable area and/or the hole ratio on the active matrix LED acoustically transparent screen 200.

In some embodiments, the perforable area occupies at least 8.0% of the circuit substrate 210. In some embodiments, the perforable area occupies at least 10.0 % of the circuit substrate 210. In some embodiments, the perforable area occupies at least 25.0 % of the circuit substrate 210. In some embodiments, the perforable area occupies at least 30.0 % of the circuit substrate 210.

The ratio of the holes 260 to the circuit substrate 210 is less than or equal to the proportion of the perforable area to the circuit substrate 210. In some embodiments, the holes 260 occupy at least 6.0% of the circuit substrate 210. In some embodiments, the holes 260 occupy at least 8.0% of the circuit substrate 210. In some embodiments, the holes 260 occupy at least 20.0% of the circuit substrate 210. In some embodiments, the holes 260 occupy at least 25.0 % of the circuit substrate 210.

In the embodiments shown in FIG. 6, in the perforable area, for the active matrix LED pixel packages 240, the holes 260 are arranged in alternate rows and alternate columns. That is, for the active matrix LED pixel packages 240, if there is a hole 260 between a row of active matrix LED pixel packages 240 and the adjacent upper row, there will be no holes 260 between this row and the adjacent lower row, and if there is a hole 260 between a column of active matrix LED pixel packages 240 and the adjacent left column, there will be no holes 260 between this column and the adjacent right column.

In some embodiments, the active matrix LED pixel packages 240 in the same row are arranged at the same first pitch D1. In some embodiments, the first pitch D1 is the distance between the center points of adjacent active matrix LED pixel packages 240 in the same row. In some embodiments, the first pitch D1 is between 2.00 mm and 6.00 mm, for example, it may be about 2.56 mm, or about 5.12 mm. In some embodiments, the active matrix LED pixel packages 240 in the same column are also arranged at the same first pitch D1.

In some embodiments, the holes 260 in the same row are arranged at the same second pitch D2. In some embodiments, the second pitch D2 is the distance between the center points of adjacent holes 260 in the same row. In some embodiments, the second pitch D2 is between 2.00 mm and 9.00 mm. In some embodiments, the holes 260 in the same column are also arranged at the same second pitch D2, but the disclosure is not limited thereto.

The second pitch D2 may be the same as or different from the first pitch D1. In some embodiments, the ratio of the second pitch D2 to the first pitch D1 is between 1.5 and 2.5. That is, the distance between the holes 260 is greater than the distance between the active matrix LED pixel packages 240.

In some embodiments, the size of one of the active matrix LED pixel packages 240 is smaller than the size (e.g., diameter) of one of the holes 260. In some embodiments, the size of each of the active matrix LED pixel packages 240 is smaller than the size of each of the holes 260. In some embodiments, the size 260S of any of the holes 260 is greater than 1.50 mm.

In some embodiments, the size 260S of any of the holes 260 is related to the first pitch D1. In some embodiments, the size 260S of any of the holes 260 is not greater than the first pitch D1 minus 0.90 mm. For example, if the first pitch D1 is 5.12 mm, the size 260S of any of the holes 260 is at most 4.22 mm.

In some embodiments, when the first pitch D1 is 5.12 mm and the size 260S of any one of the holes 260 is slightly larger than 1.50 mm, the hole ratio on the active matrix LED acoustically transparent screen 200 is approximately 6.3%.

Next, refer to FIGS. 7A to 7D to understand different configurations of the holes 260, and the same or similar elements will be labeled with the same or similar reference numerals. FIGS. 7A, 7B, 7C, and 7D are partially enlarged schematic views of active matrix LED acoustically transparent screens 200A, 200B, 200C, and 200D according to some embodiments of the present disclosure. The active matrix LED acoustically transparent screens 200A, 200B, 200C, and 200D include a plurality of holes 260A, 260B, 260C, and 260D, respectively.

In the embodiments shown in FIG. 7A, in the perforable area, for the active matrix LED pixel package 240, the holes 260A are arranged between adjacent rows and adjacent columns. That is, for the active matrix LED pixel package 240, there is a hole 260A between each row of active matrix LED pixel package 240 and the adjacent upper row, there is also a hole 260A between each row of active matrix LED pixel package 240 and the adjacent lower row, there is a hole 260A between each column of active matrix LED pixel package 240 and the adjacent left column, and there is also a hole 260A between each column of active matrix LED pixel package 240 and the adjacent right column.

In some embodiments, the active matrix LED pixel packages 240 in the same row are arranged at the same third pitch D3. In some embodiments, the holes 260A in the same row are arranged at the same fourth pitch D4. In some embodiments, the third pitch D3 may be substantially the same as the fourth pitch D4. In some embodiments, when the third pitch D3 is 2.56 mm and the size of any one of the holes 260A is slightly larger than 1.50 mm, the hole ratio on the active matrix LED acoustically transparent screen 200A is approximately 25.0%.

In the embodiments shown in FIG. 7B, in the perforable area, for the active matrix LED pixel packages 240, the holes 260B are arranged in a staggered manner. The active matrix LED pixel packages 240 in the same row are arranged at the same fifth pitch D5, and the holes 260B in the same row are arranged at the same sixth pitch D6. In some embodiments, the sixth pitch D6 is greater than the fifth pitch D5.

In the embodiments shown in FIG. 7C, in the perforable area, the holes 260C have different sizes 260CS and 260CS1. For example, in order to reduce the possibility of damaging the DDIC element 250, the size 260CS of the holes 260C farther from the DDIC element 250 may be designed to be different from the size 260CS1 of the holes 260C closer to the DDIC element 250. For example, the size 260CS of the holes 260C is larger than the size 260CS1 of the holes 260C, but the present disclosure is not limited thereto.

In the embodiments shown in FIG. 7D, in the perforable area, the shape of the holes 260D is quadrilateral. Since the area between four active matrix LED pixel packages 240 is also quadrilateral, such a design may simplify the process of forming the holes. However, the holes 260D may also include other shapes, such as any polygon, ellipse, etc.

It should be noted that the features of the various embodiments described above may be combined. For example, the perforable area may include holes of different sizes and shapes, which may be arranged in a dense or alternating configuration.

To sum up, some embodiments of the present disclosure provide an active matrix LED acoustically transparent screen, which includes a plurality of active matrix LED pixel packages. Each active matrix LED pixel package is packaged with an LED driving control element. Active matrix driving uses digital signals for control and does not require scanning lines. Compared to passive matrix driving that requires scanning lines, the present disclosure may simplify circuit routing and effectively utilize space. In addition, because the passive matrix driving require scanning lines, it may produce flicker phenomena. The active matrix driving may provide higher uniformity and/or higher stability.

Furthermore, active matrix driving may shorten the signal transmission path, thereby improving the performance of the active matrix LED acoustically transparent screen, including but not limited to contrast, clarity, etc. Moreover, because the present disclosure adopts active driving, its circuit routing is relatively simple, and the proportion of the perforable area on the active matrix LED acoustically transparent screen is relatively high, thereby increasing the flexibility of designing holes and taking the overall strength of the active matrix LED acoustically transparent screen into account. The present disclosure may effectively increase the proportion of the perforable area on the active matrix LED acoustically transparent screen and/or the hole ratio on the active matrix LED acoustically transparent screen. In addition, the present disclosure also provides a variety of possible configurations of holes on the active matrix LED acoustically transparent screen, including arrangements, sizes, shapes, etc.

The foregoing outlines features of several embodiments, so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced in the following description. Those skilled in the art should also realize that such equivalent constructions do not depart from the spirit and scope of the present disclosure, and that they may make various changes, substitutions, and alterations in the following description without departing from the spirit and scope of the present disclosure.

What is claimed is:

1. An active matrix LED acoustically transparent screen, comprising:
a circuit substrate, comprising a perforable area occupying at least 8.0% of the circuit substrate;
a plurality of active matrix LED pixel packages provided on the circuit substrate;
a plurality of data lines electrically connected to the plurality of active matrix LED pixel packages;
a plurality of clock lines electrically connected to the plurality of active matrix LED pixel packages; and
a plurality of holes penetrating through the circuit substrate, and formed in the perforable area,
wherein the perforable area does not overlap the active matrix LED pixel packages, the plurality of data lines, and the plurality of clock lines.

2. The active matrix LED acoustically transparent screen as claimed in claim 1, wherein the holes occupy at least 6.0% of the circuit substrate.

3. The active matrix LED acoustically transparent screen as claimed in claim 1, wherein the perforable area occupies at least 30.0% of the circuit substrate, and the holes occupy at least 25.0% of the circuit substrate.

4. The active matrix LED acoustically transparent screen as claimed in claim 1, wherein the plurality of holes comprises a hole, the plurality of active matrix LED pixel packages comprises an active matrix LED pixel package smaller than the hole.

5. The active matrix LED acoustically transparent screen as claimed in claim 1, wherein the plurality of active matrix LED pixel packages is arranged in first multiple rows, within each of the first multiple rows, the plurality of active matrix LED pixel packages is arranged at a first pitch.

6. The active matrix LED acoustically transparent screen as claimed in claim 5, wherein the first pitch is between 2.00 mm and 6.00 mm.

7. The active matrix LED acoustically transparent screen as claimed in claim 5, wherein the plurality of holes comprises a hole having a size which is not greater than the first pitch minus 0.90 mm.

8. The active matrix LED acoustically transparent screen as claimed in claim 5, wherein the plurality of holes is arranged in second multiple rows, within each of the second multiple rows, the plurality of holes is arranged at a second pitch.

9. The active matrix LED acoustically transparent screen as claimed in claim 8, wherein the second pitch is different from the first pitch.

10. The active matrix LED acoustically transparent screen as claimed in claim 8, wherein a ratio of the second pitch to the first pitch is between 1.5 and 2.5.

11. The active matrix LED acoustically transparent screen as claimed in claim 1, wherein the plurality of the active matrix LED pixel packages comprises an active matrix LED pixel package which comprises one or more red sub-pixels, one or more green sub-pixels, one or more blue sub-pixels, and an LED driving control element.

12. The active matrix LED acoustically transparent screen as claimed in claim 11, wherein the one or more red sub-pixels comprise a red LED chip, the one or more green sub-pixels comprise a green LED chip, and the one or more blue sub-pixels comprise a blue LED chip.

13. The active matrix LED acoustically transparent screen as claimed in claim 11, wherein the one or more red pixels comprise a first blue LED chip and a first light adjustment unit, the one or more green pixels comprise a second blue LED chip and a second light adjustment unit, and the one or more blue pixels comprise a third blue LED chip.

14. The active matrix LED acoustically transparent screen as claimed in claim 13, wherein the first light adjustment unit comprises a first light extraction layer, a first wavelength conversion layer, and a first filter layer, and the second light adjustment unit comprises a second light extraction layer, a second wavelength conversion layer, and a second filter layer.

15. The active matrix LED acoustically transparent screen as claimed in claim 1, further comprising a display driver IC element, wherein the plurality of active matrix LED pixel packages and the display driver IC element are disposed on two opposite surfaces of the circuit substrate, respectively, and the display driver IC element does not overlap the perforable area.

16. The active matrix LED acoustically transparent screen as claimed in claim 1, wherein the plurality of active matrix LED pixel packages is arranged in multiple rows and multiple columns, and the plurality of holes comprise a hole arranged between two adjacent rows of the multiple rows and between two adjacent columns of the multiple columns.

17. The active matrix LED acoustically transparent screen as claimed in claim 1, wherein the plurality of active matrix LED pixel packages is arranged in multiple rows and multiple columns, and the plurality of holes is arranged in an alternating configuration.

18. The active matrix LED acoustically transparent screen as claimed in claim 1, wherein the plurality of holes is formed in different sizes.

19. The active matrix LED acoustically transparent screen as claimed in claim 18, wherein the plurality of holes comprises first hole farther from the display driver IC element, and a second hole closer to the display driver IC element, the first hole and the second hole have different sizes.

20. The active matrix LED acoustically transparent screen as claimed in claim 19, wherein the first hole is greater than the second hole.
